(19) United States
(12) Patent Application Publication
(10) Pub. No.: US 2011/0041765 A1
(43) Pub. Date: Feb. 24, 2011

(54) FILM DEPOSITION DEVICE

(75) Inventors: Tatsuya FUJINAMI, Kanagawa (JP); Shinsuke TAKAHASHI, Kanagawa (JP); Kouji TONOHARA, Kanagawa (JP); Jun FUJINAWA, Kanagawa (JP)

Correspondence Address: YOUNG & THOMPSON, 209 Madison Street, Suite 500, Alexandria, VA, 22314, US

(73) Assignee: FUJIFILM CORPORATION, Tokyo (JP)

(21) Appl. No.: 12/862,213

(22) Filed: Aug. 24, 2010

(30) Foreign Application Priority Data
Aug. 24, 2009 (JP) 2009-192892

(51) Int. Cl. C23C 16/52

(52) U.S. Cl. 118/719

(57) ABSTRACT

The film deposition device includes a CVD film forming room disposed on a travel path of a substrate and having a function of performing the film deposition on a substrate by CVD, a treatment room disposed upstream or downstream of the CVD film forming room on the travel path and having a function of performing a predetermined treatment on the substrate, and a differential room disposed between and communicating with the CVD film forming room and the treatment room. The differential room includes a evacuation unit, a gas introducing unit for introducing at least one of a gas to be supplied to both of the CVD film forming room and the treatment room, and an inert gas, and a controller which controls the evacuation unit and the gas introducing unit to keep the differential room at a higher pressure than the CVD film forming room and the treatment room.

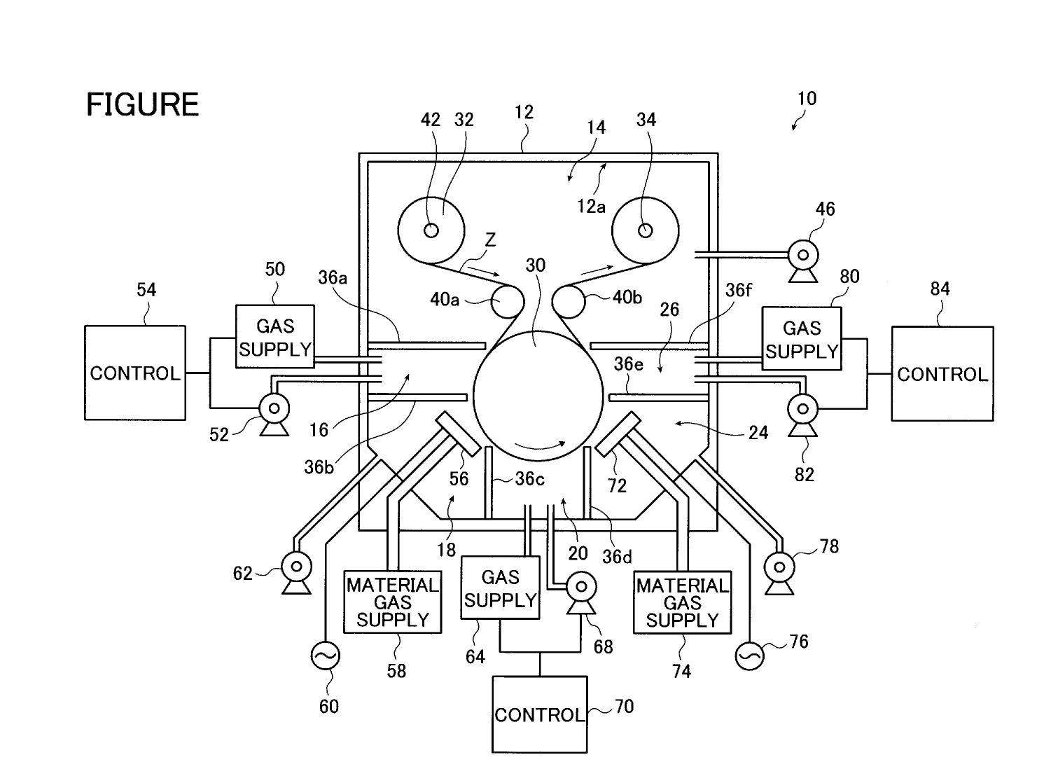

### BACKGROUND OF THE INVENTION

The present invention relates to a film deposition device suitable to produce gas barrier films. The present invention more specifically relates to a film deposition device in which a plurality of treatments including film formation by means of CVD are continuously carried out as an elongated substrate travels, and which can eliminate adverse effects of the pressure in the other treatment rooms and material gases while also suppressing contamination of the device with the material gases used in CVD.

Various functional films (functional sheets) including gas barrier films, protective films, and optical films such as optical filters and antireflection films are used in various devices including optical devices, display devices such as liquid crystal displays and organic EL displays, semiconductor devices, and thin-film solar batteries.

These functional films have been produced by film formation (thin film formation) through vacuum deposition techniques such as sputtering and plasma-enhanced CVD.

Continuous deposition of a film on an elongated substrate is preferred for efficient film formation with high productivity by a vacuum deposition technique.

A typical apparatus known in the art for carrying out such a film formation method is a so-called roll-to-roll film deposition apparatus using a feed roll into which an elongated substrate (a web of substrate) is wound and a take-up roll into which the substrate having a film formed thereon is wound. This roll-to-roll film deposition apparatus continuously forms a film on the elongated substrate in a film deposition room as the substrate travels from the feed roll to the take-up roll on a predetermined path including the film deposition room for depositing a film on the substrate, with the substrate fed from the feed roll in synchronism with the winding of the substrate having the film formed thereon on the take-up roll.

A film formed on a substrate in functional films such as gas barrier films and protective films (i.e., film (layer) for obtaining various functions) is not limited to a monolayer type but a plurality of layers may often be deposited to form a functional film.

For example, functional films may be produced by forming a layer by plasma-enhanced CVD and another layer thereon by sputtering or plasma-enhanced CVD. Instead of the formation of a plurality of layers, there is also a case in which film formation by plasma-enhanced CVD is followed by etching or plasma treatment on the film surface and optionally film formation on the thus treated surface by sputtering or plasma-enhanced CVD.

Such treatments may often be carried out in a vacuum at a predetermined pressure (under reduced pressure). In the roll-to-roll film deposition apparatus, it is not efficient for the substrate to travel in the air and in a vacuum alternately and it is preferred to connect treatment rooms for treatments in a vacuum, and continuously and sequentially carry out each treatment as the substrate travels in a vacuum.

Various treatments in a vacuum are not always carried out at the same pressure. Therefore, when treatment rooms having different treatment pressures are connected to each other, a gas may enter (penetrate into) a lower-pressure room from a higher-pressure room through a communicating portion around the substrate travel path. Such penetration of an unwanted gas may hinder proper treatment or cause contamination of the treatment room.

A known method to solve such a problem involves providing a differential room between adjacent treatment rooms to prevent the upstream-side and downstream-side treatment rooms from adversely affecting each other.

For example, JP 2004-95677 A describes a substrate treatment apparatus which subjects a substrate to film formation by means of CVD or sputtering, and to etching, laser annealing and other treatments, and which includes a drum (pass roll) on which the substrate travels, treatment rooms disposed in a circumferential direction of the drum, and differential rooms (differential evacuation rooms) disposed between the adjacent treatment rooms so that the internal pressure of the differential rooms may be lower than that of the adjacent treatment rooms.

### SUMMARY OF THE INVENTION

As described in JP 2004-95677 A, in an apparatus which continuously carried out a plurality of treatments on an elongated substrate as it travels, a gas in a treatment room can be prevented from entering its adjacent upstream- and downstream-side treatment rooms by providing differential rooms between the adjacent treatment rooms through which the treatment is continuously carried out and evacuating the differential rooms so that the internal pressure of the differential rooms may be lower than that of the adjacent treatment rooms.

However, in the apparatus which includes the differential rooms between the adjacent treatment rooms so that the pressure of the differential rooms may be lower than that of the treatment rooms, if the treatment rooms include a CVD film forming room, a reactive gas in the CVD film forming room may enter the differential rooms to deposit or form a film therein.

Therefore, maintenance including apparatus cleaning requires much time, thus leading to a decrease in the use efficiency and work efficiency of the device.

In order to solve the aforementioned prior art problems, an object of the present invention is to provide a film deposition device which carries out film deposition in a plurality of treatment rooms including a CVD film forming room as an elongated substrate continuously travels in a longitudinal direction, for example, a device which continuously carries out film deposition in a plurality of treatment rooms facing the peripheral surface of a drum as the substrate travels on the drum, the film deposition device including a differential room to prevent an adverse effect, that is, contamination with an unwanted gas penetrated into the film deposition room or the treatment room, film deposition due to a reactive gas penetrated into the differential room, and adverse effects on the film formation by means of CVD and other treatments.

In order to achieve the above object, a first aspect of the present invention provides a film deposition device in which film deposition is performed on an elongated substrate which is traveling in a longitudinal direction, the film deposition device comprising: a CVD film forming room disposed on a travel path of the substrate, including a material gas supply means and a first evacuation means and having a function of performing the film deposition on the substrate by CVD; a treatment room disposed upstream or downstream of the CVD film forming room on the travel path, including a second evacuation means and having a function of performing a predetermined treatment on the substrate; and a differential room disposed between and communicating with the CVD film forming room and the treatment room on the travel path, wherein the differential room includes a third evacuation means, a gas introducing means for introducing at least one of a gas to be supplied to both of the CVD film forming room and the treatment room, and an inert gas, and a control means which controls the third evacuation means and the gas introducing means to keep the differential room at a higher pressure than the CVD film forming room and the treatment room.

The film deposition is preferably performed on the substrate in vacuum as the predetermined treatment in the treatment room.

The film deposition is preferably performed on the substrate by CVD as the predetermined treatment in the treatment room.

In the treatment room as the predetermined treatment, at least one of feed of the substrate from a substrate roll into which the substrate is wound and take-up of the substrate having undergone the film deposition in the CVD film forming room are preferably performed.

Preferably, the film deposition device further comprises one vacuum chamber, and the CVD film forming room, the treatment room and the differential room are disposed in the one vacuum chamber.

Preferably, the film deposition device includes a drum on an outer peripheral surface of which the substrate travels, and at least one of the CVD film forming room, the treatment room and the differential room forms a room with the outer peripheral surface of the drum.

Each of the CVD film forming room, the treatment room and the differential room preferably forms a room with the outer peripheral surface of the drum.

The control means preferably keeps the differential room at a higher pressure by at least 5 Pa than one of the CVD film forming room and the treatment room which has a higher pressure than the other.

The CVD film forming room preferably has a function of depositing a gas barrier film by plasma-enhanced CVD.

A second aspect of the present invention provides a film deposition device in which film deposition is performed on an elongated substrate which is traveling in a longitudinal direction, the film deposition device comprising: at least one CVD film forming room disposed on a travel path of the substrate and having a function of performing the film deposition on the substrate by CVD; differential rooms disposed on the travel path so that the at least one CVD film forming room is interposed between and communicates with the differential rooms; at least one film deposition treatment room disposed on the travel path and having a function of performing the film deposition on the substrate in vacuum; a first treatment room disposed at an upstream end of the travel path and having a function of feeding the substrate from a substrate roll into which the substrate is wound; and a second treatment room disposed at a downstream end of the travel path and having a function of winding the substrate having undergone the film deposition in the at least one CVD film forming room, wherein at least one treatment room of the at least one film deposition treatment room, the first treatment room and the second treatment room communicates with the differential rooms and is disposed so as to be adjacent to the at least one CVD film forming room via the differential rooms, and wherein each of the differential rooms includes an evacuation means, a gas introducing means for introducing at least one of a gas to be supplied to both of the at least one CVD film forming room and the at least one treatment room adjacent thereto, and an inert gas, and a control means which controls the evacuation means and the gas introducing means to keep the differential rooms at a higher pressure than the at least one CVD film forming room and the at least one treatment room adjacent thereto.

The inventive film deposition device having been configured as above carries out film deposition in a plurality of treatment rooms including a CVD film forming room as an elongated substrate continuously travels in a longitudinal direction and includes a differential room between adjacent treatment rooms to prevent an unwanted gas to enter (penetrate into) the CVD film forming room or treatment room to adversely affect the treatment or cause contamination.

The pressure of the differential room is set higher than that of the adjacent rooms, thus preventing penetration of a reactive gas for use in CVD into the differential room and also film deposition in the differential room and its contamination. In addition, a gas to be supplied to both the adjacent treatment rooms or an inert gas is supplied to the differential room so that the differential room may have a higher pressure than that of the adjacent rooms, and therefore there is no adverse effect on the CVD film formation or the treatment in the treatment rooms.

### BRIEF DESCRIPTION OF THE DRAWINGS

The FIGURE is a schematic view showing an embodiment of a film deposition device of the present invention.

### DETAILED DESCRIPTION OF THE INVENTION

Next, the film deposition device of the present invention is described in detail by referring to the preferred embodiments shown in the accompanying drawing.

The FIGURE is a schematic view showing an embodiment of a film deposition device of the present invention.

A film deposition device 10 shown in the FIGURE is a device capable of deposition of a two-layer film on a substrate Z by plasma-enhanced CVD, and includes a vacuum chamber 12 as well as a feed and take-up room 14, a first differential room 16, a first film deposition room 18, a second differential room 20, a second film deposition room 24, a third differential room 26 and a drum 30 formed in the vacuum chamber 12.

In the present invention, the substrate Z is not particularly limited but elongated films (sheets) capable of CVD film formation as exemplified by resin films such as polyethylene terephthalate (PET) films and metallic films are all available.

The substrate used may be a film obtained by forming layers (films) for exhibiting various functions (e.g., planarizing layer, protective layer, adhesion layer, light-reflecting layer, antireflection layer) on a resin film serving as a base.

In the film deposition device 10, the substrate Z in a web form is fed from a substrate roll 32 of the feed and take-up room 14, travels on the drum 30 in a longitudinal direction and is subjected to sequential film deposition in the first film deposition room 18 and the second film deposition room 24 before being rewound on a take-up shaft 34 in the feed and take-up room 14 (rewound into a roll).

The drum 30 is a cylindrical member which rotates counterclockwise around the central axis in the FIGURE.

The drum 30 causes the substrate Z guided by a guide roller 40a of the feed and take-up room 14 to be described below along a predetermined path and held at a predetermined position in a predetermined region of the outer peripheral surface to travel in the longitudinal direction and sequentially pass through the first differential room 16, the first film deposition room 18, the second differential room 20, the second film deposition room 24 and the third differential room 26 to reach a guide roller 40b of the feed and take-up room 14.

The drum 30 also serves as a counter electrode of a shower head electrode 56 in the first film deposition room 18 and a shower head electrode 72 in the second film deposition room 24 to be described later and forms an electrode pair with the shower head electrode 56 and an electrode pair with the shower head electrode 72.

To this end, the drum 30 is connected to a bias power source or grounded (connection is not shown in both the cases). Alternatively, the drum 30 may be capable of switching between connection to the bias power source and grounding.

The drum 30 may serve as a means for adjusting the temperature of the substrate Z during the film deposition in the first film deposition room 18 and the second film deposition room 24. Therefore, the temperature adjusting means is preferably built into the drum 30. The temperature adjusting means of the drum 30 is not particularly limited and various types of temperature adjusting means including one in which a refrigerant is circulated and a cooling means using a Peltier element are all available.

The feed and take-up room 14 is defined by an inner wall 12a of the vacuum chamber 12, the outer peripheral surface of the drum 30, and partition walls 36a and 36f extending from the inner wall 12a to the vicinity of the outer peripheral surface of the drum 30.

The ends of the partition walls 36a and 36f opposite from the inner wall of the vacuum chamber 12 approach the outer peripheral surface of the drum 30 till the position where the ends do not come in contact with the substrate Z in a stationary state to separate the feed and take-up room 14 from the first differential room 16 and the third differential room 26 in a substantially air-tight manner. The other partition walls also have the same function in this regard.

The feed and take-up room 14 includes the take-up shaft 34, the guide rollers 40a and 40b, a rotary shaft 42 and a vacuum evacuation means 46.

The guide rollers 40a and 40b are of an ordinary type guiding the substrate Z on a predetermined travel path. The take-up shaft 34 is of a known type for elongated sheets which winds up the substrate Z after the film deposition.

In the illustrated case, the substrate roll 32 into which the substrate Z in an elongated shape is wound is mounted on the rotary shaft 42. Upon mounting of the substrate roll 32 on the rotary shaft 42, the substrate Z is passed along a predetermined path including the guide roller 40a, the drum 30 and the guide roller 40b to reach the take-up shaft 34.

In the film deposition device 10, the substrate Z is fed from the substrate roll 32 in synchronism with the winding of the substrate Z having a film formed thereon on the take-up shaft 34 to sequentially carry out film deposition in the first film deposition room 18 and the second film deposition room 24 as the substrate Z in an elongated shape travels on the predetermined travel path in the longitudinal direction. Therefore, the feed and take-up room 14 is the most upstream room and also the most downstream room in the direction of travel of the substrate Z in the film deposition device 10.

The vacuum evacuation means 46 evacuates the feed and take-up room 14 to reduce its pressure in accordance with the pressure of the first film deposition room 18 and the second film deposition room 24 (film deposition pressure) to prevent the pressure in the feed and take-up room 14 from which the substrate Z is fed and where the substrate Z is wound up, from adversely affecting the film deposition in the first film deposition room 18 and the second film deposition room 24.

In the present invention, the vacuum evacuation means 46 is not particularly limited, and exemplary means that may be used include vacuum pumps such as a turbo pump, a mechanical booster pump, a rotary pump and a dry pump, an assist means such as a cryogenic coil, and various other known (vacuum) evacuation means which use a means for adjusting the ultimate degree of vacuum or the amount of air discharged and are employed in vacuum deposition devices.

In this regard, the same holds true for the other vacuum evacuation means.

The first differential room 16 is provided downstream of the feed and take-up room 14 in the direction of travel of the substrate Z.

The first differential room 16 is defined by the inner wall 12a, the outer peripheral surface of the drum 30, and partition walls 36a and 36b extending from the inner wall 12a to the vicinity of the outer peripheral surface of the drum 30. The first differential room 16 includes a gas supply means 50, a vacuum evacuation means 52 and a control means 54.

The vacuum evacuation means 52 evacuates the first differential room 16. The gas supply means 50 is of a known type used in vacuum deposition devices such as plasma CVD devices to supply a predetermined gas to the first differential room 16.

In the present invention, the gas supply means for supplying a gas to the differential room (means for introducing a gas to the differential room) supplies to the differential room a gas to be supplied to both of the adjacent CVD device and treatment room, and/or an inert gas.

In the illustrated case, the treatment room adjacent to the first differential room 16 is the feed and take-up room 14 where the substrate Z is fed from the substrate roll 32 and the substrate Z having a film formed thereon is wound up, and no gas is basically introduced therein. Therefore, the gas supply means 50 supplies inert gases such as nitrogen gas, argon gas and helium gas to the first differential room 16.

The control means 54 controls the evacuation made by the vacuum evacuation means 52 and the amount of gas supplied from the gas supply means 50 so that the internal pressure of the first differential room 16 may be higher than that of the adjacent treatment rooms including the feed and take-up room 14 and the first film deposition room 18 (or one of the feed and take-up room 14 and the first film deposition room 18 which has a higher pressure than the other).

This point will be described later in further detail.

The first film deposition room 18 is provided downstream of the first differential room 16.

The first film deposition room 18 is defined by the inner wall 12a, the outer peripheral surface of the drum 30, and partition walls 36b and 36c extending from the inner wall 12a to the vicinity of the outer peripheral surface of the drum 30.

In the film deposition device 10, the first film deposition room 18 carries out film deposition by capacitively coupled plasma-enhanced CVD (hereinafter abbreviated as “CCP-CVD”) on the surface of the substrate Z and includes the shower head electrode 56, a material gas supply means 58, an RF power source 60, and a vacuum evacuation means 62.

The shower head electrode 56 is of a known type used in CCP-CVD.

In the illustrated case, the shower head electrode 56 is, for example, in the form of a hollow rectangular solid and is disposed so that its largest surface faces the outer peripheral surface of the drum 30. A large number of through holes are formed at the whole surface of the shower head electrode 56 facing the drum 30. The surface of the shower head electrode 56 facing the drum 30 may be curved so as to follow the outer peripheral surface of the drum 30.

In the illustrated embodiment, one shower head electrode (film deposition means using CCP-CVD) is provided in the first film deposition room 18. However, this is not the sole case of the present invention and a plurality of shower head electrodes may be disposed in the direction of travel of the substrate Z. In this regard, the same holds true when using plasma-enhanced CVD of other type than CCP-CVD. For example, when an inorganic layer is formed by ICP-CVD, a plurality of coils for forming an induced electric field (induced magnetic field) may be provided along the direction of travel of the substrate Z.

The present invention is not limited to the case in which the shower head electrode 56 is used, and a common electrode in plate form and a material gas supply nozzle may be used.

The material gas supply means 58 is of a known type used in vacuum deposition devices such as plasma CVD devices, and supplies a gas material into the shower head electrode 56.

As described above, a large number of through holes are formed at the surface of the shower head electrode 56 facing the drum 30. Therefore, the material gas supplied into the shower head electrode 56 passes through the through holes to be introduced into the space between the shower head electrode 56 and the drum 30.

The RF power source 60 is one for supplying plasma excitation power to the shower head electrode 56. Known RF power sources used in various plasma CVD devices can be all used for the RF power source 60.

In addition, the vacuum evacuation means 62 evacuates the first film deposition room 18 to keep it at a predetermined film deposition pressure in order to form a film by plasma-enhanced CVD.

In the present invention, the method of depositing a film in the CVD film forming room is not limited to the illustrated CCP-CVD and known CVD techniques including plasma-enhanced CVD such as inductively coupled plasma-enhanced CVD (ICP-CVD) and microwave plasma CVD, catalytic CVD (Cat-CVD) and thermal CVD.

The film deposited in the CVD film forming room of the film deposition device of the present invention is not particularly limited and films that can be deposited by CVD are all usable. Particularly preferred examples of the film include gas barrier films made of silicon oxide, aluminum oxide and silicon nitride.

In other words, particles generated by delamination of a film deposited or formed in an unwanted area of the device diffuse to adhere to the substrate surface or the film surface, or to penetrate into the film, thus lowering the quality of the film deposited by plasma-enhanced CVD. Such adhesion or penetration of particles is a major cause of a film defect and particularly in the gas barrier film, the film defect is the most major cause of reduced gas barrier properties.

As will be described later in detail, the film deposition device of the present invention can considerably suppress deposition and formation of a film in an unwanted area of the device. Therefore, the present invention is employed with particular advantage to deposit the gas barrier film because particles due to the delamination of a film deposited in an unwanted area can be prevented from diffusing and a high-quality gas barrier film having no deteriorated gas barrier properties resulting from the particles can be deposited in a consistent manner.

As described above, the film deposition device 10 evacuates the feed and take-up room 14 as well to prevent the pressure of the feed and take-up room 14 from adversely affecting the film deposition pressure of the first film deposition room 18 or the second film deposition room 24.

In the film deposition device 10, the first differential room 16 is provided between the feed and take-up room 14 as the treatment room and the first film deposition room 18 as the CVD film forming room so that the internal pressure of the first differential room 16 may be higher or at a lower degree of vacuum than that of the adjacent feed and take-up room 14 and first film deposition room 18.

As described above, in the apparatus which continuously treat the substrate in the treatment rooms connected to each other as it travels, an unwanted gas was prevented from penetrating into the treatment rooms such as the film deposition room by evacuating the differential rooms provided to prevent the penetration of an unwanted gas from the treatment rooms connected thereto so that the differential rooms may have a lower pressure than the treatment rooms connected thereto.

However, in cases where the treatment rooms include a CVD film forming room, a material gas for use in CVD penetrates into the differential rooms and deposits a film therein, and such a configuration brings about hard maintenance and reduced workability.

In contrast, in the present invention, the differential room has a higher pressure than the adjacent rooms, whereby the gas in the first film deposition room 18 can be prevented from entering or penetrating into the feed and take-up room 14 and the first differential room 16. Therefore, the material gas used for CVD does not enter the feed and take-up room 14 or the first differential room 16 to deposit or form a film therein.

The pressure in the first differential room 16 is set higher than the feed and take-up room 14 and the first film deposition room 18, but the gas supplied to the first differential room 16, that is, the gas entering the feed and take-up room 14 and the first film deposition room 18 through the first differential room 16 includes an inert gas (and/or a gas supplied to both the rooms between which the differential room is disposed) and therefore does not adversely affect the film deposition in the first film deposition room 18, nor are there penetration of impurities into the film being formed, contamination of the interior of the feed and take-up room 14, or adverse effects on the substrate Z within the room.

In other words, in the film deposition device which carries out film deposition in a plurality of treatment rooms including a CVD film forming room as an elongated substrate continuously travels in a longitudinal direction, the present invention can prevent a gas in the CVD film forming room from entering a treatment room and vice versa to adversely affect the treatment or cause contamination, and also prevent penetration of a CVD reactive gas into the differential room, that is, film deposition and contamination of the differential room.

An inert gas and/or a gas to be supplied to both the adjacent treatment rooms is supplied to the differential room and therefore the supplied gas does not adversely affect the CVD film formation or the treatment in the treatment rooms.

The aforementioned effect of the present invention is also achieved between the first film deposition room 18, the second differential room 20, and the second film deposition room 24, and between the second film deposition room 24, the third differential room 26 and the feed and take-up room 14.

There is no particular limitation on the difference between the pressure of the feed and take-up room 14 and the first film deposition room 18 and the pressure of the first differential room 16 disposed therebetween, but the first differential room 16 should have a slightly higher pressure than that of the adjacent rooms.

In other words, the pressure of the first differential room 16 should be appropriately set higher than that of the feed and take-up room 14 and the first film deposition room 18 according to the pressure of the feed and take-up room 14 (treatment room interposing the differential room together with the CVD film forming room) and the first film deposition room 18, the difference between the pressure of the feed and take-up room 14 and that of the first film deposition room 18, and the capacity of the vacuum evacuation means disposed in the feed and take-up room 14 and the first film deposition room 18 so as not to adversely affect the pressure of the feed and take-up room 14 and the first film deposition room 18 and so as to minimize adverse effects if any.

According to the study made by the inventors of the present invention, the pressure of the first differential room 16 (differential room) is preferably set higher by at least 5 Pa than one of the feed and take-up room 14 and the first film deposition room 18 having the higher pressure, because the film deposition pressure in CVD is usually from a few Pa to several hundred Pa.

Such a layout enables the first differential room 16 to separate the feed and take-up room 14 and the first film deposition room 18 from each other while more reliably preventing the gas in the first film deposition room 18 from entering the first differential room 16, and is therefore preferred.

Because the adverse effect of the pressure in the differential room on the pressure in its adjacent rooms can be minimized, the difference between the pressure of the first differential room 16 and that of one of the feed and take-up room 14 and the first film deposition room 18 having the higher pressure is preferably 10 Pa or less.

The same holds true for the second differential room 20 and the third differential room 26.

The second differential room 20 is provided downstream of the first film deposition room 18.

The second differential room 20 is defined by the inner wall 12a, the outer peripheral surface of the drum 30, and partition walls 36c and 36d extending from the inner wall 12a to the vicinity of the outer peripheral surface of the drum 30.

The second differential room 20 includes a gas supply means 64, a vacuum evacuation means 68 and a control means 70. As in the first differential room 16, the vacuum evacuation means 68 evacuates the second differential room 20 and the gas supply means 64 is of a known type supplying a predetermined gas to the second differential room 20.

The gas supply means 64 supplies to the second differential room 20 a material gas to be supplied to the first film deposition room 18 and the second film deposition room 24 and/or an inert gas.

Therefore, the gas supply means 64 may supply to the second differential room 20 not the inert gas but the material gas to be supplied to both the film deposition rooms. More specifically, in cases where the material gas used in the first film deposition room 18 and the second film deposition room 24 is hydrogen gas, not the inert gas but the hydrogen gas may be supplied to the second differential room 20.

The gas supply means 64 may of course supply the inert gas to the second differential room 20. The material gas to be used in the first film deposition room 18 and the second film deposition room 24 and the inert gas may both be supplied to the second differential room 20.

As in the aforementioned control means 54, the control means 70 controls the evacuation made by the vacuum evacuation means 64 and the amount of gas supplied from the gas supply means 64 so that the internal pressure of the second differential room 20 may be higher than that of the first film deposition room 18 and the second film deposition room 24.

The second film deposition room 24 is provided downstream of the second differential room 20.

The second film deposition room 24 is defined by the inner wall 12a, the outer peripheral surface of the drum 30, and partition walls 36d and 36e extending from the inner wall 12a to the vicinity of the outer peripheral surface of the drum 30.

As in the first film deposition room 18, the second film deposition room 24 carries out film deposition by CCP-CVD on the substrate Z or the substrate Z having a film deposited in the first film deposition room 16.

Therefore, the second film deposition room 24 includes the shower head electrode 72, a material gas supply means 74, an RF power source 76 and a vacuum evacuation means 78 which are similar to the shower head electrode 56, the material gas supply means 58, the RF power source 60 and the vacuum evacuation means 62 in the first film deposition room 18.

As in the first film deposition room 18, the layout of the second film deposition room 24 is not limited to this.

As in the first film deposition room 18, the film to be deposited in the second film deposition room 24 is not particularly limited and films capable of formation by means of CVD are all usable.

In the film deposition device 10, the film deposited in the second film deposition room 24 may be the same as or different from the film deposited in the first film deposition room 18. In cases where the same type of film is deposited in the first film deposition room 18 and the second film deposition room 24, both the film deposition rooms may apply the same or different film deposition conditions such as the film deposition pressure, amount of material gas supplied and film deposition rate.

The third differential room 26 is provided downstream of the second film deposition room 24.

The third differential room 26 is defined by the inner wall 12a, the outer peripheral surface of the drum 30, and partition walls 36e and 36f extending from the inner wall 12a to the vicinity of the outer peripheral surface of the drum 30.

The third differential room 26 includes a gas supply means 80, a vacuum evacuation means 82 and a control means 84 which are similar to those in the first differential room 16 and the second differential room 20.

The feed and take-up room 14 is located downstream of the third differential room 26. In other words, the third differential room 26 is disposed between the second film deposition room 24 and the feed and take-up room 14. As described above, the feed and take-up room 14 is evacuated depending on the pressure of the first film deposition room 18 or the second film deposition room 24 but no gas is basically supplied thereto.

Therefore, the gas supply means 80 supplies the inert gas to the third differential room 26 as in the first differential room 16.

As in the aforementioned control means 54, the control means 84 controls the evacuation made by the vacuum evacuation means 82 and the amount of gas supplied from the gas supply means 80 so that the internal pressure of the third differential room 26 may be slightly higher than one of the second film deposition room 24 and the feed and take-up room 14 having the higher pressure.

The operation of the film deposition device 10 is described below.

As described above, upon mounting of the substrate roll 32 on the rotary shaft 42, the substrate Z is let out from the substrate roll 32 and is passed along a predetermined travel path including the guide roller 40a, the drum 30 and the guide roller 40b to reach the take-up shaft 34.

Once the substrate Z has been passed through the travel path, the vacuum chamber 12 is closed and the vacuum evacuation means 46, 52, 62, 68, 78 and 82 are driven to start evacuation of the respective rooms.

Once the feed and take-up room 14, the first differential room 16, the first film deposition room 18, the second differential room 20, the second film deposition room 24 and the third differential room 26 are all evacuated to a predetermined degree of vacuum or less, the gas supply means 50, 64 and 80 are driven to introduce predetermined gases to the respective differential rooms, and the material gas supply means 58 and 74 are driven to supply the material gases to both the film deposition rooms.

As described above, the respective control means adjust the pressure so that the first differential room 16 may have a higher pressure than the feed and take-up room 14 and the first film deposition room 18, the second differential room 20 may have a higher pressure than the first film deposition room 18 and the second film deposition room 24, and the third differential room 26 may have a higher pressure than the second film deposition room 24 and the feed and take-up room 14.

As also described above, the inert gas is supplied to the first differential room 16 and the third differential room 26, and the material gas to be supplied to each of the first film deposition room 18 and the second film deposition room 24 and/or the inert gas is supplied to the second differential room 20.

Once the pressure in all the rooms has stabilized at a predetermined value, the rotation of the drum 30 is started to start traveling of the substrate Z and the RF power sources 60 and 76 are driven to start film deposition on the substrate Z in the film deposition room 18 and the second film deposition room 24 as the substrate Z travels in the longitudinal direction.

As described above, according to the present invention, the differential rooms are provided between the feed and take-up room 14 and its adjacent film deposition room and between the adjacent film deposition rooms, and an inert gas or the same gas as in the film deposition rooms is introduced so that the differential rooms may have a higher pressure than the adjacent rooms.

Therefore, the gases in the film deposition rooms do not enter the feed and take-up room 14 to enable contamination of the feed and take-up room 14 and contamination of the substrate Z before and after the film deposition to be prevented. The gases in the film deposition rooms also do not enter the differential rooms to enable contamination of the differential rooms and deposition and formation of a film to be further prevented. The gas supplied to the differential rooms is an inert gas or a gas to be supplied to both the adjacent treatment rooms and therefore do not adversely affect the film deposition.

As is clear from the above, the feed and take-up room 14 and the second film deposition room 24 in the illustrated film deposition device 10 serve as the treatment rooms in the present invention in cases where the first film deposition room 18 is used as the CVD film forming room in the present invention. On the other hand, in cases where the second film deposition room 24 is used as the CVD film forming room of the present invention, the first film deposition room 18 and the feed and take-up room 14 serve as the treatment rooms in the present invention.

In other words, the illustrated film deposition device 10 can also be deemed to include in total three film deposition devices of the present invention which includes a film deposition device having the feed and take-up room 14, the first differential room 16 and the first film deposition room 18, a film deposition device having the first film deposition room 18, the second differential room 20 and the second film deposition room 24, and a film deposition device having the second film deposition room 24, the third differential room 26 and the feed and take-up room 14.

The film deposition device of the present invention is not limited to this type and may be of a type only including a CVD film forming room, a differential room and a treatment room. Alternatively, the film deposition device of the present invention may be of a type including two or at least four film deposition devices of the present invention.

The illustrated film deposition device 10 uses the feed and take-up room 14 where feed of the substrate Z to be treated and take-up of the substrate Z having undergone the film deposition are both performed. However, this is not the sole case of the present invention and the film deposition device 10 may be configured such that a feed room (first treatment room) for feeding the substrate Z from the substrate roll and a take-up room (second treatment room) for winding the substrate Z having undergone the film deposition are provided as separate entities.

In other words, the film deposition device of the present invention may include at least one CVD film forming room, a feed room, a take-up room, and differential rooms disposed between the CVD film forming room and the feed room, and between the CVD film forming room and the take-up room, respectively. In cases where the film deposition device of the present invention includes a plurality of CVD film forming rooms, the film deposition device also includes other differential room(s) disposed between adjacent two CVD film forming rooms. In cases where the film deposition device of the present invention also has at least one film deposition treatment room where vacuum deposition is performed, the film deposition device further includes another differential room disposed between the CVD film forming room and the film deposition treatment room.

In the illustrated film deposition device 10, the feed and take-up room 14, the first differential room 16, the first film deposition room 18, the second differential room 20, the second film deposition room 24 and the third differential room 26 are sequentially disposed around the periphery of the drum 30. However, the present invention is not limited to this and may be configured such that the feed and take-up room 14 is divided into the feed room and the take-up room, and the feed room, the first differential room 16, the first film deposition room 18, the second differential room 20, the second film deposition room 24, the third differential room 26 and the take-up room are sequentially disposed in line from the upstream side of the travel path of the substrate.

The feed room for feeding the substrate Z from the substrate roll may be separated from the take-up room for winding up the substrate Z after the film deposition.

The treatment room in the present invention is not limited to one where film formation by means of plasma-enhanced CVD or feed/take-up of the substrate is carried out, and various rooms for carrying out various treatments on the substrate as exemplified by a treatment room for film deposition by sputtering or vacuum evaporation and a treatment room for plasma treatment or etching can be employed as long as the treatment room includes a vacuum evacuation means.

While the film deposition device of the present invention has been described above in detail, the present invention is by no means limited to the foregoing embodiment and it should be understood that various improvements and modifications are possible without departing from the scope and spirit of the present invention.

### EXAMPLES

Next, the present invention is described in further detail by referring to the Examples.

### Example 1

The film deposition device 10 shown in the FIGURE was used to deposit a silicon nitride film on a substrate Z.

The substrate Z used was a PET film (Cosmoshine A4300 available from Toyobo Co., Ltd.).

Silane gas (at a flow rate of 100 sccm), ammonia gas (at a flow rate of 100 sccm) and nitrogen gas (at a flow rate of 800 sccm) were used as the material gases to form the silicon nitride film by means of CCP-CVD. The gas used to supply to the differential rooms was nitrogen gas (at a flow rate of 1000 sccm).

The film deposition pressure of the first film deposition room 18 and the second film deposition room 24 was set to 30 Pa and 20 Pa, respectively, and the first differential room 16 and the second differential room 20 were set to a pressure of 35 Pa, whereas the third differential room 26 was set to a pressure of 25 Pa.

In addition, the power sources used were RF power sources at a frequency of 13.56 MHz and the plasma excitation power supplied to the shower head electrodes was 1 kW.

In the film deposition device 10, a silicon nitride film was deposited on the substrate Z with a length of 1000 m under the foregoing conditions and the interior of the three differential rooms was visually checked. As a result, film deposition was not confirmed at all in all of the differential rooms and rated good in the evaluation item to be referred to later.

### Examples 2 and 3 and Comparative Example 1

In Example 2, Example 1 was repeated except that argon gas was introduced into the differential rooms to form a silicon nitride film on the substrate Z with a length of 1000 m, and the interior of the three differential rooms was visually checked and evaluated.

In Example 3, Example 1 was repeated except that the amount of evacuation of each differential room by means of the vacuum evacuation means was regulated to adjust the pressure of the first differential room 16 and the second differential room 20 to 32 Pa, and the third differential room 26 to 22 Pa to form a silicon nitride film on the substrate Z with a length of 1000 m, and the interior of the three differential rooms was visually checked and evaluated.

In Comparative Example 1, Example 1 was repeated except that the amount of evacuation of each differential room by means of the vacuum evacuation means was regulated to adjust the pressure of all of the first differential room 16, the second differential room 20 and the third differential room 26 to 10 Pa to form a silicon nitride film on the substrate Z with a length of 1000 m, and the interior of the three differential rooms was visually checked and evaluated.

A case in which film deposition was not confirmed at all in all of the differential rooms was rated good.

A case in which slight film deposition was confirmed in at least one of the differential rooms was rated fair.

A case in which a large amount of film deposition was confirmed in at least one of the differential rooms was rated poor.

The pressure of the respective rooms and the evaluation results are shown in Table 1 together with those of Example 1.

TABLE 1

| | Pressure | | | | |
|---|---|---|---|---|---|
| | First | Second | Third | | |
| | differential | differential | differential | Gas supplied | |
| | unit | unit | unit | to differential unit | Evaluation |
| Example 1 | 35 | 35 | 25 | Nitrogen gas | Good |
| Example 2 | 35 | 35 | 25 | Argon gas | Good |
| Example 3 | 32 | 32 | 22 | Nitrogen gas | Fair |
| Comparative | 10 | 10 | 10 | Nitrogen gas | Poor |
| Example 1 | | | | | |

In all the examples, the first film deposition unit, the second film deposition unit, and the feed and take-up unit were set to a pressure of 30 Pa, 20 Pa and 15 Pa, respectively.

As shown in Table 1, the present invention is capable of considerably improving the workability and the ease of maintenance of the film deposition device while considerably reducing film deposition in the differential room.

The above results clearly show the beneficial effects of the present invention.

The present invention can considerably improve the ease of maintenance and the workability of the film deposition device and be therefore advantageously used to produce gas barrier films.

What is claimed is:

1. A film deposition device in which film deposition is performed on an elongated substrate which is traveling in a longitudinal direction, the film deposition device comprising:
a CVD film forming room disposed on a travel path of said substrate, including a material gas supply means and a first evacuation means and having a function of performing the film deposition on said substrate by CVD;
a treatment room disposed upstream or downstream of said CVD film forming room on the travel path, including a second evacuation means and having a function of performing a predetermined treatment on said substrate; and
a differential room disposed between and communicating with said CVD film forming room and said treatment room on said travel path,
wherein said differential room includes a third evacuation means, a gas introducing means for introducing at least one of a gas to be supplied to both of said CVD film forming room and said treatment room, and an inert gas, and a control means which controls said third evacuation means and said gas introducing means to keep said differential room at a higher pressure than said CVD film forming room and said treatment room.

2. The film deposition device according to claim 1, wherein the film deposition is performed on said substrate in vacuum as said predetermined treatment in said treatment room.

3. The film deposition device according to claim 2, wherein the film deposition is performed on said substrate by CVD as said predetermined treatment in said treatment room.

4. The film deposition device according to claim 1, wherein, in said treatment room as said predetermined treatment, at least one of feed of said substrate from a substrate roll into which said substrate is wound and take-up of said substrate having undergone the film deposition in said CVD film forming room are performed.

5. The film deposition device according to claim 1, further comprising one vacuum chamber,
wherein said CVD film forming room, said treatment room and said differential room are disposed in said one vacuum chamber.

6. The film deposition device according to claim 1, wherein said film deposition device includes a drum on an outer peripheral surface of which said substrate travels, and wherein at least one of said CVD film forming room, said treatment room and said differential room forms a room with the outer peripheral surface of said drum.

7. The film deposition device according to claim 6, wherein each of said CVD film forming room, said treatment room and said differential room forms a room with the outer peripheral surface of said drum.

8. The film deposition device according to claim 1, wherein said control means keeps said differential room at a higher pressure by at least 5 Pa than one of said CVD film forming room and said treatment room which has a higher pressure than the other.

9. The film deposition device according to claim 1, wherein said CVD film forming room has a function of depositing a gas barrier film by plasma-enhanced CVD.

10. A film deposition device in which film deposition is performed on an elongated substrate which is traveling in a longitudinal direction, the film deposition device comprising:
at least one CVD film forming room disposed on a travel path of said substrate and having a function of performing the film deposition on said substrate by CVD;
differential rooms disposed on said travel path so that said at least one CVD film forming room is interposed between and communicates with said differential rooms;
at least one film deposition treatment room disposed on said travel path and having a function of performing the film deposition on said substrate in vacuum;
a first treatment room disposed at an upstream end of said travel path and having a function of feeding said substrate from a substrate roll into which said substrate is wound; and
a second treatment room disposed at a downstream end of said travel path and having a function of winding said substrate having undergone the film deposition in said at least one CVD film forming room,
wherein at least one treatment room of said at least one film deposition treatment room, said first treatment room and said second treatment room communicates with said differential rooms and is disposed so as to be adjacent to said at least one CVD film forming room via said differential rooms, and
wherein each of said differential rooms includes an evacuation means, a gas introducing means for introducing at least one of a gas to be supplied to both of said at least one CVD film forming room and said at least one treatment room adjacent thereto, and an inert gas, and a control means which controls said evacuation means and said gas introducing means to keep said differential rooms at a higher pressure than said at least one CVD film forming room and said at least one treatment room adjacent thereto.

11. The film deposition device according to claim 10, wherein said at least one film deposition treatment room is said at least one CVD film forming room performing the film deposition on said substrate by CVD and one of said differential rooms is disposed between and communicates with adjacent two CVD film forming rooms.

12. The film deposition device according to claim 10, wherein said at least one CVD film forming room comprises a plurality of CVD film forming rooms.

13. The film deposition device according to claim 10, wherein said first treatment room and said second treatment room are unified as a feed and take-up room.

14. The film deposition device according to claim 10, further comprising one vacuum chamber,
wherein said at least one CVD film forming room, said at least one film deposition treatment room, said first treatment room, said second treatment room and said differential rooms are disposed in said one vacuum chamber.

15. The film deposition device according to claim 10, wherein said film deposition device includes a drum on an outer peripheral surface of which said substrate travels, and wherein at least one of said at least one CVD film forming room, said at least one film deposition treatment room and said differential rooms forms a room with the outer peripheral surface of said drum.

16. The film deposition device according to claim 15, wherein each of said at least one CVD film forming room, said at least one film deposition treatment room and said differential rooms forms a room with the outer peripheral surface of said drum.

17. The film deposition device according to claim 10, wherein said control means controls a pressure of said differential rooms at a higher level by at least 5 Pa than one of said at least one CVD film forming room, said at least one film deposition treatment room, said first treatment room and said second treatment room which has a highest pressure.

18. The film deposition device according to claim 10, wherein said at least one CVD film forming room has a function of depositing a gas barrier film by plasma-enhanced CVD.
